(19) United States
(12) Patent Application Publication
(10) Pub. No.: US 2014/0061456 A1
(43) Pub. Date: Mar. 6, 2014

(54) COORDINATE CORRECTING METHOD, DEFECT IMAGE ACQUIRING METHOD AND ELECTRON MICROSCOPE

(71) Applicant: KABUSHIKI KAISHA TOSHIBA, Tokyo (JP)

(72) Inventor: Kouta Kameishi, Yokkaichi-shi (JP)

(73) Assignee: Kabushiki Kaisha Toshiba, Tokyo (JP)

(21) Appl. No.: 13/780,170

(22) Filed: Feb. 28, 2013

Related U.S. Application Data
(60) Provisional application No. 61/694,796, filed on Aug. 30, 2012.

(51) Int. Cl. H01J 37/26

(52) U.S. Cl. CPC H01J 37/263
USPC 250/252.1; 250/310

(57) ABSTRACT

In accordance with an embodiment, a coordinate correcting method includes generating a pattern image for matching from an SEM image acquired by an electron microscope in accordance with a defect coordinate, performing matching between a defect image and the pattern image, superimposing the defect image and the pattern image between which the matching has been performed on a difference image, specifying a position to which a defect position on the difference image corresponds on the pattern image, and converting the corresponding position on the SEM image to a coordinate on a wafer. The defect coordinate, the defect image and the difference image are obtained by a defect inspection apparatus.

### CROSS REFERENCE TO RELATED APPLICATIONS

This application is based upon and claims the benefit of U.S. provisional Application No. 61/694,796, filed on Aug. 30, 2012, the entire contents of which are incorporated herein by reference.

### FIELD

Embodiments described herein relate generally to a coordinate correcting method, a defect image acquiring method and an electron microscope.

### BACKGROUND

A scanning electron microscope (hereinafter briefly referred to as an “SEM”) is widely used to observe the structure of a semiconductor device. Recently, an automatic defect reviewer (hereinafter briefly referred to as an “SEM ADR”) has also been used to automatically defect a defect and acquire an observation image (hereinafter referred to as an “SEM image”).

When a low-magnification SEM image has a defect, a normal SEM ADR compares the SEM image with a reference image to extract a defective portion, and then acquires a high-magnification SEM image.

However, when a particular pattern has a process variation such as fabrication unevenness and a plurality of defects detected by a defect inspection apparatus are present in a low-magnification SEM viewing field at the same time, a high-magnification SEM image of a desired defect detected by the defect inspection apparatus may be unsuccessfully acquired.

### BRIEF DESCRIPTION OF THE DRAWINGS

In the accompanying drawings:

FIG. 1 is a block diagram showing a general configuration of an electron microscope according to an embodiment;

FIG. 2 is a flowchart showing a general procedure of a coordinate correcting method according to an embodiment; and

FIG. 3 is a view illustrating a method of acquiring a defect image by use of the coordinate correcting method shown in FIG. 2.

### DETAILED DESCRIPTION

In accordance with an embodiment, a coordinate correcting method includes generating a pattern image for matching from an SEM image acquired by an electron microscope in accordance with a defect coordinate, performing matching between a defect image and the pattern image, superimposing the defect image and the pattern image between which the matching has been performed on a difference image, specifying a position to which a defect position on the difference image corresponds on the pattern image, and converting the corresponding position on the SEM image to a coordinate on a wafer. The defect coordinate, the defect image and the difference image are obtained by a defect inspection apparatus.

Embodiments will now be explained with reference to the accompanying drawings. Like components are provided with like reference signs throughout the drawings and repeated descriptions thereof are appropriately omitted.

(1) Electron Microscope

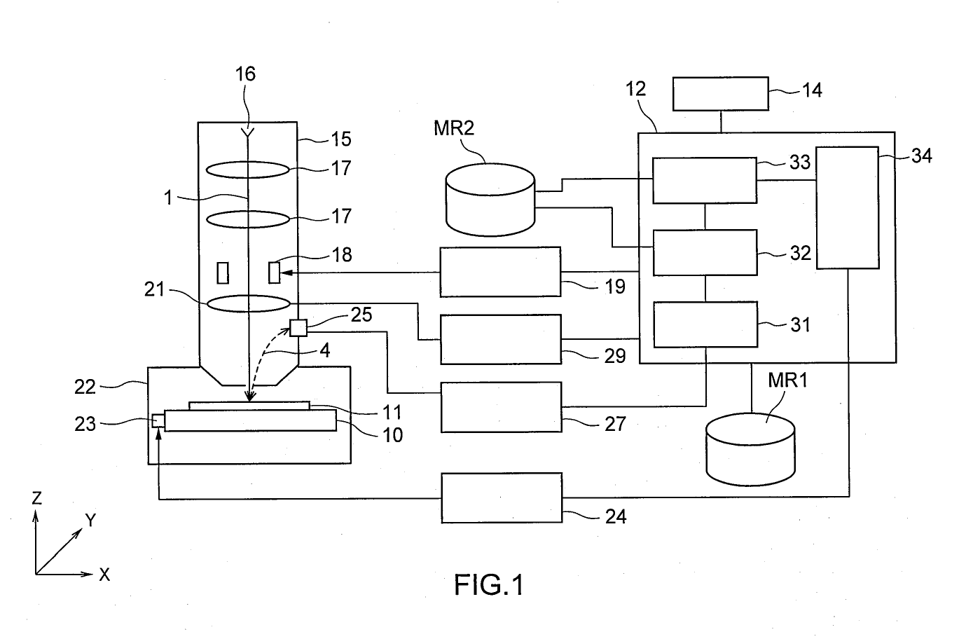

FIG. 1 is a block diagram showing a general configuration of an electron microscope according to Embodiment 1. The electron microscope shown in FIG. 1 includes an electron beam column 15, a sample chamber 22, a control computer 12, a deflection controller 19, an objective lens controller 29, an actuator controller 24, a signal processor 27, a monitor 14, and recording devices MR1 and MR2.

The electron beam column 15 is provided with an electronic optical system including an electron gun 16, a condenser lens 17, a deflector 18, and an objective lens 21, and a detector 25.

A stage 10 which supports a semiconductor wafer 11 having an inspection target pattern formed thereon, and an actuator 23 are provided in the sample chamber 22. In the present embodiment, the electronic optical system corresponds to, for example, an electron beam applying unit, and the semiconductor wafer 11 corresponds to, for example, a sample. The sample is not limited to the semiconductor wafer, and may be, for example, a glass substrate or a ceramic substrate as long as the inspection target pattern is formed thereon.

The control computer 12 is connected to the deflection control circuit 19, the objective lens controller 29, the signal processor 27, and the actuator controller 24. The deflection controller 19 and the objective lens controller 29 are connected to the deflector 18 and the objective lens 21 in the electron beam column 15, respectively. The actuator controller 24 is connected to the actuator 23 in the sample chamber 22. The signal processor 27 is connected to the detector 25. The control computer 12 is also connected to the monitor 14 and the recording devices MR1 and MR2.

The recording device MR2 is configured to store a defect image, a difference image for use in defect detection, and defect coordinate data that are acquired by an external defect inspection apparatus (not shown). The recording device MR2 is also configured to temporarily store a later-described misalignment amount, a pattern image, and various superimposed images.

An electron beam 1 emitted from the electron gun 16 is condensed by the condenser lens 17, and its focal position is then adjusted by the objective lens 21. The electron beam 1 is then applied to the semiconductor wafer 11.

The deflection controller 19 generates a deflection control signal in accordance with the instruction from the control computer 12. The deflector 18 forms a deflection electric field or deflection magnetic field in accordance with the deflection control signal supplied from the deflection controller 19, and then appropriately deflects the electron beam 1 in an X-direction and a Y-direction to scan the surface of the semiconductor wafer 11.

The objective lens controller 29 generates a focus control signal in accordance with the instruction from the control computer 12. The objective lens 21 forms an electric field or magnetic field in accordance with the focus control signal supplied from the objective lens controller 29 to control the focal position of the electron beam 1, and adjusts the magnification of an SEM image. In the present embodiment, the control computer 12 and the objective lens controller 29 correspond to, for example, a focal position control unit.

In response to the application of the electron beam 1, secondary electrons and reflected electrons 4 are generated from the surface of the semiconductor wafer 11 and detected by the detector 25, and a detection signal is then sent to the signal processor 27. In the present embodiment, the detector 25 corresponds to, for example, a detection unit.

The stage 10 is movable in the X-direction and the Y-direction, and moves in the X-direction and the Y-direction when the actuator 23 is driven in accordance with a stage control signal which is generated by the actuator control circuit 24 in accordance with the instruction from the control computer 12. The stage 10 may be configured to be movable not only in an X-Y two-dimensional plane but also in a three-dimensional space in any of the X-, Y-, and Z-directions in conformity to the inspection target pattern. Moreover, the stage 10 may be configured to be able to incline the wafer 11 at any angle of inclination. In the present embodiment, the control computer 12, the actuator control circuit 24, and the actuator 23 correspond to, for example, a stage control unit.

The signal processor 27 processes the detection signal sent from the detector 25 to form an SEM image of the pattern on the surface of the semiconductor wafer 11, and supplies the SEM image to the control computer 12. In the present embodiment, the signal processor 27 corresponds to, for example, an image generating unit.

The control computer 12 includes a pattern image generator 31, a matching section 32, a defect-corresponding position specifying section 33, and a coordinate converter 34.

The pattern image generator 31 is connected to the signal processor 27. The pattern image generator 31 makes the monitor 14 display the SEM image when provided with the SEM image from the signal processor 27, and generates a later-described alignment pattern image and supplies the alignment pattern image to the matching section 32.

The matching section 32 is connected to the recording device MR2. The matching section 32 extracts, from the recording device MR2, the defect image acquired from the external defect inspection apparatus (not shown), performs matching between the defect image and the alignment pattern image, calculates a misalignment amount, and supplies the misalignment amount to the defect specifying section 33.

The defect specifying section 33 is connected to the recording device MR2. The defect specifying section 33 extracts, from the recording device MR2, the difference image acquired from the external defect inspection apparatus (not shown), superimposes the difference image on the defect image and the alignment pattern image matched by the matching section 32, specifies a position to which a defect position on the difference image corresponds on the alignment pattern image, and supplies information on the specified position to the coordinate converter 34.

Receiving the information on the defect-corresponding position on the specified alignment pattern image, the coordinate converter 34 converts the defect-corresponding position to a coordinate on the wafer 11.

The coordinate converter 34 then generates a control signal in accordance with information on the converted coordinate on the wafer 11, and supplies the control signal to the actuator controller 24. A stage control signal generated by the actuator controller 24 is supplied to the actuator 23 to drive the stage 11, and the stage 10 is thereby moved in such a manner that the converted coordinate position on the wafer 11 will be located in the center of a viewing field.

The recording device MR1 is configured to store a recipe file in which specific procedures of a coordinate correcting method and a defect image acquiring method that will be described below are written. The control computer 12 reads the recipe file from the recording device MR1, and then executes the procedures of the coordinate correcting method and the defect image acquiring method.

(2) Coordinate Correcting Method and Defect Image Acquiring Method

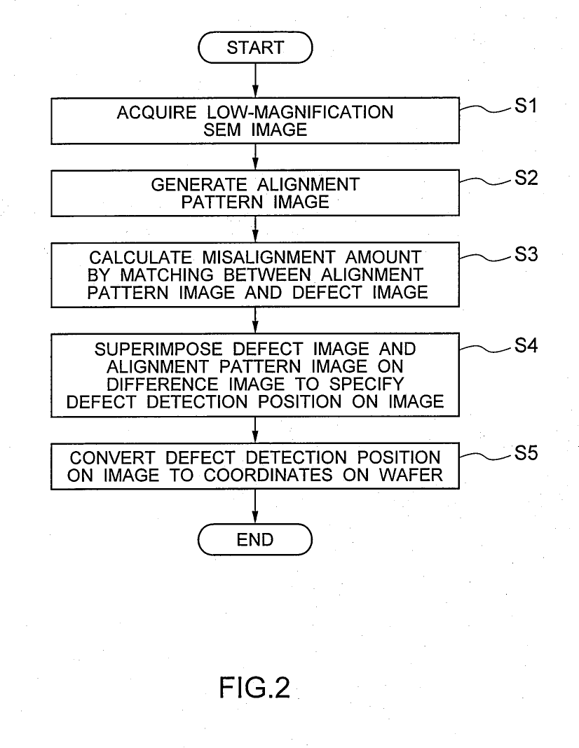

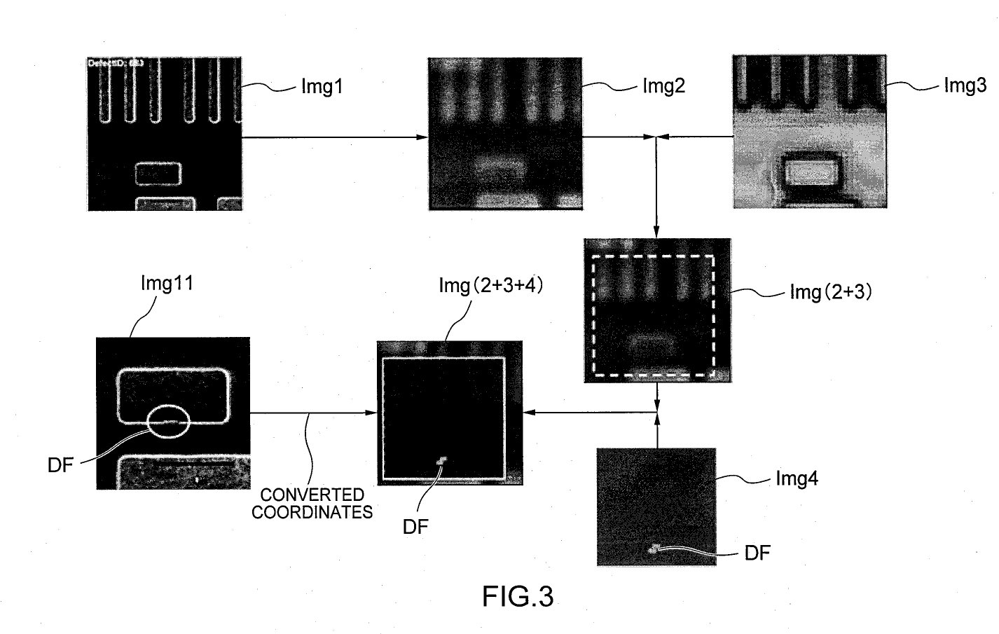

The operation of the electron microscope shown in FIG. 1 is described with reference to FIG. 2 and FIG. 3 as embodiments of the coordinate correcting method and the defect image acquiring method.

The general procedure of the coordinate correcting method according to the embodiment is initially described with reference to a flowchart in FIG. 2.

First, the control computer 12 extracts, from the recording device MR2, the defect coordinate data acquired and recorded from the external defect inspection apparatus (not shown), and controls the actuator 23 via the actuator controller 24. The actuator 23 moves the stage 10 in such a manner that the defect coordinate position will be located in the center of the viewing field. The semiconductor wafer 11 is scanned with the electron beam 1 via the deflection controller 19 and the objective lens controller 29 and so forth. Secondary electrons and reflected electrons generated from the surface of the sample are detected by the detector 25. The signal processor 27 processes the signal, and a low-magnification SEM image is thus acquired (step S1). In the present embodiment, the low-magnification SEM image corresponds to, for example, a first SEM image of a first magnification. The acquired low-magnification SEM image is supplied to the pattern image generator 31.

The pattern image generator 31 then extracts a feature quantity on the SEM image to generate an image (hereinafter referred to as an “alignment pattern image”) for matching with the defect image (step S2). The generated alignment pattern image is supplied to the matching section 32.

The matching section 32 then extracts, from the recording device MR2, the defect image recorded from the external defect inspection apparatus (not shown), performs matching between the defect image and the alignment pattern image, and calculates a misalignment amount between the defect image and the alignment pattern image (step S3). The calculated misalignment amount is stored in the defect-corresponding position specifying section 33. The defect image and the alignment pattern image as matching results are also stored in the recording device MR2.

The defect-corresponding position specifying section 33 then extracts, from the recording device MR2, the difference image acquired and recorded when the external defect inspection apparatus (not shown) detects a defect. The defect-corresponding position specifying section 33 superimposes the difference image on the defect image and the alignment pattern image, and thereby specifies a defect detection position on the alignment pattern image (step S4). Data on the specified defect detection position is supplied to the coordinate converter 34.

The coordinate converter 34 then converts the defect detection position data to a coordinate on the wafer 11 (step S5).

The defect detection coordinate is corrected by the procedure described above.

The actuator 23 is then driven via the actuator controller 24 to move the stage 10 in such a manner that the corrected defect detection coordinate will be located in the center of the viewing field. Thus, a high-magnification SEM image is acquired.

More specific procedures of the coordinate correcting method and the defect image acquiring method above will be described with reference to FIG. 3.

(a) Acquisition of Low-Magnification SEM Image (step S1)

An SEM image Img1 shown at the upper left of FIG. 3 is an example of an SEM image recorded from the external defect inspection apparatus (not shown) and acquired with a low magnification regarding the defect coordinate position. As apparent from the comparison with a defect image Img3 by the defect inspection apparatus (not shown), the pattern on the semiconductor wafer 11 can be clearly recognized even from the low-magnification SEM image Img1.

(b) Generation of Alignment Pattern Image (step S2)

As the difference of image quality between the SEM image Img1 and the defect image Img3 by the defect inspection apparatus (not shown) is thus great, alignment is difficult in this state. Therefore, the image is processed so as to enable alignment. It is difficult to increase the quality of the defect image Img3 to the same level as the SEM image Img1. Accordingly, the pattern image generator 31 processes the SEM image Img1 to deteriorate the level of its clearness. A specific way of the image processing is to extract a feature quantity on the SEM image Img1 and use the extracted feature quantity for filtering. The feature quantity includes, for example, the value of the contrast of the image, pattern edge information, and the degree of pattern sparsity/density.

In the example shown in FIG. 3, attention is focused on the sparsity/density of the pattern on the SEM image Img1, and pixels constituting the image are Fourier-transformed and passed through a predetermined low-pass filter, and the image with high contrast is removed. In this way, an alignment pattern image indicated by the sign Img2 is obtained.

(c) Pattern Matching Between Defect Image and Alignment Pattern Image (step S3)

Pattern matching is performed between the alignment pattern image Img2 generated as described above and the defect image Img3 to calculate the distance and direction in which the center of the defect image Img3 has deviated from the central position of the alignment pattern image Img2. In the pattern matching, it is possible to freely enlarge or reduce the image or adjust the contrast if necessary.

An example of the result of the pattern matching is shown by an image Img(2+3) in FIG. 3. It is shown from the image Img(2+3) that the center of the defect image Img3 has deviated downward from the central position of the alignment pattern image Img2. Here, the deviation amount is supposed as (±ΔX, ±Δy).

(d) Specification of Defect Detection Position (Step S4)

An image Img4 as an example of the difference image acquired by the external defect inspection apparatus (not shown) is shown at the lower right of FIG. 3. A defect DF is detected in the lower region of the image Img4. Here, the position of the defect DF from the center in the difference image Img4 is supposed as (X, Y).

The image Img4 is then further superimposed on the image Img(2+3) after the pattern matching. As long as the difference image Img4 is an image acquired at the time of defect detection, the positions always correspond to each other between the defect image Img3 and the difference image Img4. As a result, the deviation amount (±ΔX, ±Δy) is carried over as it is when the difference image Img4 is superimposed on the image Img(2+3).

(e) Coordinate Conversion

Using the deviation amount (±ΔX, ±Δy) between the defect image Img3 and the alignment pattern image Img2 and data on the defect position (X, Y) in the difference image Img4, the coordinate converter 34 specifies a position to which the defect position on the difference image Img4 corresponds on the SEM image, and converts the corresponding position on the specified SEM image to a coordinate on the wafer. The defect coordinate on the SEM image are thus corrected.

(f) Acquisition of High-Magnification SEM Image

Finally, the actuator 23 is driven via the actuator controller 24 to move the stage 10 in such a manner that the converted coordinate on the wafer will be located in the center of the viewing field. The focal position of the objective lens is controlled via the objective lens controller 29, and a high-magnification SEM image is acquired. In the present embodiment, the high-magnification SEM image corresponds to, for example, a second SEM image of a second magnification.

An SEM image Img11 shown at the lower left of FIG. 3 is as an example of the high-magnification SEM image obtained by the procedure described above. It is shown that the defect DF is accurately imaged in an encircled part located slightly below the center of the SEM image Img11.

According to the above-described at least one embodiment, the electron microscope does not need to acquire a referential image for extracting defect candidates, and an SEM image of a defective portion can be accurately acquired in a short time.

(3) Program and Non-Transitory Recording Medium

A series of procedures of the coordinate correcting method and the defect image acquiring method described above may be incorporated in a program, and read into and executed by a control computer of the electron microscope. This enables the coordinate correcting method and the defect image acquiring method described above to be carried out by use of a general-purpose electron microscope. A series of procedures of the coordinate correcting method and the defect image acquiring method described above may be stored in a recording medium such as a flexible disk or a CD-ROM as a program to be executed by the control computer of the electron microscope, and read into and executed by the control computer.

The non-transitory recording medium is not limited to a portable medium such as a magnetic disk or an optical disk, and may be a fixed recording medium such as a hard disk drive or a memory. The program incorporating the series of procedures of the coordinate correcting method and the defect image acquiring method described above may be distributed via a communication line (including wireless communication) such as the Internet. Moreover, the program incorporating the series of procedures of the coordinate correcting method and the defect image acquiring method described above may be distributed in an encrypted, modulated or compressed state via a wired line or a wireless line such as the Internet or in a manner stored in a recording medium.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A coordinate correcting method comprising:
generating a pattern image for matching from an SEM image acquired by an electron microscope in accordance with a defect coordinate obtained by a defect inspection apparatus;
performing matching between a defect image acquired by the defect inspection apparatus and the pattern image;
superimposing the defect image and the pattern image between which the matching has been performed on a difference image obtained by the defect inspection apparatus;
specifying a position to which a defect position on the difference image corresponds on the pattern image; and
converting the corresponding position on the SEM image to a coordinate on a wafer.

2. The method of claim 1, further comprising extracting a feature quantity from the SEM image,
wherein the pattern image is generated by use of the feature quantity.

3. The method of claim 2,
wherein the feature quantity is a value of the contrast of the SEM image.

4. The method of claim 2,
wherein the feature quantity is pattern edge information.

5. The method of claim 2,
wherein the feature quantity is the degree of the sparsity/density of a pattern.

6. The method of claim 1,
wherein performing the matching comprises calculating a deviation amount between the defect image and the pattern image.

7. The method of claim 6,
wherein the defect image and the pattern image are superimposed on the difference image in accordance with the deviation amount.

8. The method of claim 7,
wherein the corresponding position is specified from the defect position and the deviation amount.

9. A defect image obtaining method comprising:
generating a pattern image for matching from an SEM image of a first magnification acquired by an electron microscope in accordance with a defect coordinate obtained by a defect inspection apparatus;
performing matching between a defect image acquired by the defect inspection apparatus and the pattern image;
superimposing the defect image and the pattern image between which the matching has been performed on a difference image obtained by the defect inspection apparatus;
specifying a position to which a defect position on the difference image corresponds on the pattern image;
converting the corresponding position on the first SEM image to a coordinate on a wafer; and
acquiring an SEM image with a second magnification higher than the first magnification by the electron microscope in accordance with the converted coordinate on the wafer.

10. The method of claim 9, further comprising extracting a feature quantity from the SEM image,
wherein the pattern image is generated by use of the feature quantity.

11. The method of claim 10,
wherein the feature quantity is a value of the contrast of the SEM image.

12. The method of claim 10,
wherein the feature quantity is pattern edge information.

13. The method of claim 10,
wherein the feature quantity is the degree of the sparsity/density of a pattern.

14. The method of claim 9,
wherein performing the matching comprises calculating a deviation amount between the defect image and the pattern image.

15. The method of claim 14,
wherein the defect image and the pattern image are superimposed on the difference image in accordance with the deviation amount.

16. The method of claim 15,
wherein the corresponding position is specified from the defect position and the deviation amount.

17. An electron microscope comprising:
a stage configured to support a sample on which an inspection target pattern is formed;
a stage control unit configured to move the stage;
an electron beam applying unit configured to apply an electron beam to the sample;
a detection unit configured to detect secondary electrons and reflected electrons generated from the sample by the application of the electron beam and to output a signal;
an image generating unit configured to process the signal to generate an SEM image of the sample;
a focal position control unit configured to control the focal position of the electron beam on the sample to control the magnification of the SEM image; and
a control unit configured to control the stage control unit, the focal position control unit, the electron beam applying unit, the detection unit, and the image generating unit to acquire an SEM image of a desired magnification at a desired position on the sample,
wherein the control unit is further configured to:
acquire a first SEM image of a first magnification in accordance with defect a coordinate supplied from an external defect inspection apparatus, and generate a pattern image for matching from the first SEM image;
perform matching between a defect image supplied from the defect inspection apparatus and the pattern image;
superimpose the defect image and the pattern image between which the matching has been performed on a difference image supplied from the defect inspection apparatus;
specify a position to which a defect position on the difference image corresponds on the pattern image; and
convert the specified corresponding position on the SEM image to a coordinate on a wafer, and acquire a second SEM image of a second magnification higher than the first magnification regarding the converted coordinate on the wafer.

18. The electron microscope of claim 17, wherein
the control unit extracts a feature quantity from the first SEM image, and generates the pattern image by use of the extracted feature quantity.

19. The electron microscope of claim 17, wherein
the control unit is further configured to calculate a deviation amount between the defect image and the pattern image by the matching.

20. The electron microscope of claim 19, wherein
the control unit is further configured to superimpose the defect image and the pattern image on the difference image in accordance with the deviation amount.
